(19) United States
(12) Patent Application Publication
(10) Pub. No.: US 2019/0281726 A1
(43) Pub. Date: Sep. 12, 2019

(54) COMPRESSIBLE THERMALLY CONDUCTIVE ARTICLES

(71) Applicant: ROGERS CORPORATION, Chandler, AZ (US)

(72) Inventor: Joseph Puglisi, Stafford Springs, CT (US)

(21) Appl. No.: 16/331,211

(22) PCT Filed: Sep. 6, 2017
(86) PCT No.: PCT/US2017/050171

§ 371 Date: Mar. 7, 2019

Related U.S. Application Data
(60) Provisional application No. 62/384,392, filed on Sep. 7, 2016.

(51) Int. Cl. H05K 7/20; C09K 5/14; H05K 1/02

(52) U.S. Cl. CPC H05K 7/2039; H01L 23/3737; H05K 1/0201; C09K 5/14

(57) ABSTRACT

Disclosed is a compressible and thermally conductive material in the form of a sheet comprising a plurality of elongated walls substantially parallel in an x-y plane, wherein the elongated walls comprise particles of thermally conductive filler dispersed in a polymeric matrix material. Each of the elongated walls extends in a direction of thickness that slants from a bottom point to a top point, wherein adjacent elongated walls slant in alternate directions to a vertical line in the direction of thickness. In some embodiments, the thermally conductive sheet comprises a corrugated elastomeric sheet, having front and back surfaces, wherein the corrugated elastomeric sheet has a porosity of 0 to 25%; and wherein the corrugated elastomeric sheet is optionally embedded, at least partially, in a sheet of polymeric foam having a porosity of greater than 10%. Heat management assemblies comprising such compressible thermally conductive materials are also disclosed.

### BACKGROUND

Disclosed herein are thermally conductive articles, and in particular compressible articles. The articles are useful for providing heat management for electronic devices.

Circuit designs for electronic devices such as televisions, radios, computers, medical instruments, business machines, communications equipment, and the like have become increasingly smaller and thinner. Furthermore, the increasing power of such electronic devices has resulted in more power being squeezed into more densely packed spaces. Consequently, manufacturers are continuously facing the challenge of managing heat generation within the electronic devices.

In response to this challenge, various designs have been developed for providing heat dissipation from electronic devices. For example, U.S. Pat. No. 6,591,897 discloses a heat sink, for use in an electronic device, comprising a plurality of columnar pins mounted on the top surface of the spreader plate, wherein the pins conduct heat away from the spreader plate. A foam block is also mounted on the spreader plate and surrounds the columnar pins in order to provide compressibility, which can provide increased thermal transfer between surfaces.

U.S. Patent Pub. No. 2012/0048528 also discloses a compressible, thermally conductive foam pad. The pad is filled with ceramic fillers such as Al₂O₃ (aluminum oxide) or BN (boron nitride) particles in an amount of between 20% and 80% of the total weight of the foam pad. Various elastomeric materials, including silicon or polyurethane, provide compressibility. Due to the thickness of the pad, further compressibility is provided by a void volume comprising air-filled through-holes (vias) in the pad. When an external force or load is applied to the pad, the void volume decreases and the thermal conductivity at the thermal interface increases. The foam pad can have a thermal conductivity of at least 0.5 Watts per meter-degree Kelvin (W/m-K).

Despite the variety of materials and designs that have been proposed for thermal management in electronic devices, as exemplified by the foregoing, it is apparent that there remains a need for new and improved thermal management materials in order to more effectively dissipate heat from more compact and powerful electronic devices. A heat management system is desired that can provide improved heat transfer efficiency in combination with compact size. The heat management material are also desirably capable of economical manufacture.

### SUMMARY

Described herein is a compressible thermally conductive product adapted to be disposed between two heat transfer surfaces, for example, between the heat transfer surface of an electronic component or device and the surface of a heat sink, thereby providing a thermal pathway between the surfaces. In some embodiments, the compressible thermally conductive material is in the form of a sheet comprising a plurality of elongated walls substantially parallel in an x-y plane, wherein the elongated walls comprise particles of thermally conductive filler dispersed in a polymeric matrix material, wherein each of the elongated walls extends in a direction of thickness that slants from a bottom point to a top point, and wherein adjacent walls slant in alternate directions to a vertical line in the direction of thickness. Adjacent elongated walls, straight or curved, can optionally be connected to each other in the sheet, thereby forming an elongated ridge or elongated groove, or both, connecting the elongated walls. In other embodiments, adjacent walls can be separately spaced.

In some embodiments, the compressible thermally conductive material comprises a corrugated elastomeric sheet, having corrugated front and back surfaces, both surfaces comprising a plurality of ridges and grooves, wherein the material is formed from a composition comprising particles of thermally conductive filler dispersed in a polymeric matrix material and wherein, in a cross-sectional view through the thickness (in the z-direction) of the corrugated elastomeric sheet, sides connecting the top of the ridges and bottom of the grooves in the corrugated elastomeric sheet resiliently are slanted to form an angle of less than 90 degrees to a horizontal plane (in the x-y direction) perpendicular to the thickness of the corrugation. The corrugated elastomer sheet can have a porosity (also known as void fraction or volume fraction) of 0 to 25%. The corrugated elastomeric sheet is optionally embedded, at least partially, in a sheet of polymeric foam having a porosity greater than 10%.

In other embodiments, a compressible thermally conductive material comprises a corrugated elastomeric sheet as described above wherein in addition, the front or back surfaces, or both, of the corrugated elastomeric sheet are covered, at least partially, by polymeric foam having a porosity greater than 10%. The polymeric foam can at least partially fill the grooves, and can optionally form a surface layer completely over the back or front surface, or both, of the corrugated elastomeric sheet. In some embodiments, the polymeric foam material in the compressible thermally conductive material comprises less volume percent of thermally conductive filler, if any, than in the corrugated elastomeric sheet—or the polymeric foam material comprises greater porosity than, if any, in the corrugated elastomeric foam material, or both. Specifically, for example, the volume percent of thermally conductive filler in the corrugated elastomeric sheet can be at least a third more than in the polymeric foam material and the porosity of the polymeric foam can be at least a third more than in the corrugated elastomeric sheet. In still other embodiments, a compressible thermally conductive material comprises a foamed polymeric material having opposed upper and lower surfaces embedding a plurality of elastomeric walls, wherein in a cross-sectional view through the thickness of the foamed polymeric material, the walls alternatively slant in different directions to the front and back surfaces of the material, and wherein optionally each wall can be connected at one, but not both ends, of the wall to an adjacent wall. In an embodiment, the walls can be obtained by modifying a corrugated elastomeric sheet, having corrugated front and back surfaces, by removing a top portion of a plurality of ridges or a bottom portion of a plurality of grooves, or both. The elastomeric walls comprise particles of thermally conductive filler dispersed in a polymeric matrix material having porosity not more than 25%, and the foamed polymeric material can have a porosity of greater than 10% and optionally comprises particles of thermally conductive filler.

In other embodiments, a compressible thermally conductive material comprises walls that, in cross-sectional view through the thickness of the material, forms a plurality of columns, which columns extend, in a slanted direction, at least partially from a back surface of the foamed polymeric material to an upper surface of the foamed polymeric material, wherein consecutive adjacent columns slant in alternate directions from a vertical line in the direction of thickness of the material. In particular, in some embodiments, each of said columns are adjacent to two other columns and slant in a direction towards one of the two adjacent columns and in the direction away from the other of the two adjacent columns such that the tops of two adjacent columns alternate, in cross-sectional view, between being slanted towards each other and being slanted away from each other. During compression of the thermally conductive material, in cross-sectional view, the angle of each column to the horizontal can decrease and the distance between the tops of adjacent columns, where slanted away from each other, can increase or the distance between the tops of adjacent columns, where slanted away from each other, can decrease, or both. According to one method, columns can be formed by removing a top portion of ridges or bottom portions of grooves, or both, in a filled corrugated elastomeric sheet as described above.

Also disclosed is an assembly comprising the above-described compressible thermally conductive material wherein the front side is in direct contact with a first heat transfer surface that generates heat and the back side is in direct contact with a second heat transfer surface that functions to dissipate heat.

The above described and other features are exemplified by the following figures and detailed description.

### BRIEF DESCRIPTION OF THE DRAWINGS

FIG. 1 shows a perspective view of a thermally conductive corrugated elastomeric sheet or pad according to an embodiment;

FIG. 2 shows a cross-sectional view (through the thickness of the pad) of the corrugated elastomeric pad in the embodiment of FIG. 1;

FIG. 3 shows a cross-sectional side view of a corrugated elastomeric pad according to an alternate embodiment in which the shape of the corrugation comprises flat surfaces areas at the tops of the ridges and the bottoms of the grooves;

FIG. 4 shows a cross-sectional view of a corrugated elastomeric sheet according to another embodiment in which a layer of polymeric foam covers a back surface of the sheet;

FIG. 5 shows a cross-sectional view of a corrugated elastomeric pad according to another embodiment, wherein a layer of polymeric foam covers at least a portion of both the front and back surfaces of a corrugated elastomeric sheet; and

FIG. 6 shows a cross-sectional view of an elastomeric pad according to another embodiment such as can be obtained from a corrugated sheet by removing a top portion of each of a plurality of front ridges and a bottom portion of each of a plurality of front grooves.

### DETAILED DESCRIPTION

Described herein is a compressible thermally conductive material that includes a corrugated elastomeric sheet capable of providing significantly improved thermal conductivity. Although the terms “corrugated,” “corrugation,” or the like can generally mean a sheet material having a series of parallel ridges and grooves on only one side of the sheet material, herein these terms refer to a sheet material corrugated on both the front and back surfaces of the material. In some embodiments, corrugations that are formed on the back surface of a corrugated elastomeric sheet material correspond to, and are patterned by, corrugations on the front surface of the sheet material. Specifically, the sheet material forming ridges on one side of the sheet material can form grooves on the back-side of the sheet material.

In general, a corrugated elastomeric sheet, as defined herein, has a structure wherein the corrugated elastomeric sheet, in front plan view, comprises a plurality of rows of alternating front ridges and front grooves, wherein a side wall connects the top of each front ridge to the bottom of a front groove. The corrugated elastomeric sheet, in back plan view, also comprises rows of alternating back ridges and back grooves, wherein a side wall connects the top of each back ridge to the bottom of a back groove. The material forming back grooves can form, on the reverse side of the sheet, the front ridges, and the material forming the back ridges can form, on the reverse side of the sheet, the front grooves. Furthermore, besides being corrugated on both the front and back surfaces, the corrugated elastomeric sheet, as defined herein, the side walls of the ridges and grooves, in a cross-sectional view, resiliently form an angle β of less than 90 degrees, specifically 20 to 80 degrees, more specifically 25 to 75 degrees, and most specifically 30 to 65 degrees, to an x-y plane perpendicular to the thickness of the corrugation. (Front and back surfaces of the sheet generally extend in an x-y plane and the thickness extends in the z-direction.) The walls can be slanted at an angle that provides resilience to the corrugated elastomeric sheet when compressed, wherein adjacent walls are alternatively slanted in the direction of thickness.

The corrugated elastomeric sheet can, in top plan view, have a plurality of rows of front ridges and front grooves (and a corresponding number of back ridges and grooves). In some embodiments, the corrugated elastomeric sheet can, in top plan view, have a 1 to 20, specifically 2 to 15, more specifically 3 to 10, most specifically 4 to 8 ridges/cm.

The complete shape and dimensions of the corrugated elastomeric pad can depend on the electronic device for which it is designed to provide heat management. As mentioned above, the sides joining front ridges to adjacent front grooves in the corrugated elastomeric sheet can be at an angle β of less than 90 degrees to an x-y plane (or horizontal x-direction in cross-sectional view). In some embodiments the angle β is 20 to 70 degrees, specifically 25 to 65 degrees, more specifically 30 to 60 degrees, most specifically 35 to 55 degrees. Furthermore, in some embodiments the ratio of the peak-to-peak length to the peak vertical distance between a front ridge and an adjacent back ridge, when the pad is not compressed, can be 5:1 to 1:2.

For use in some electronic devices, the corrugated sheet can have a flat thickness (uncorrugated) of from 20 to 2000 micrometers, specifically, 50 to 500 micrometers, more specifically 100 to 300 micrometers. The corrugated elastomeric sheet, with respect to the dimensions of corrugation from top to bottom of the sheet, can have a maximum cross-sectional thickness from top to bottom of the thermally conductive pad that is 100 to 25,000 micrometers, specifically 200 to 2000 micrometers, more specifically 300 to 1500 micrometers. In some embodiments, the average thickness of the material is 0.1 to 10 mm (100 to 10,000 micrometers).

The corrugated elastomeric sheet can comprise thermally conductive filler particles dispersed in a polymeric matrix composition. The sheet material can be formed by extrusion, molding, or other conventional process. In the production of commercial quantities, the sheet can be formed into larger sheets or roll stock that can be cut into individual pieces or pads for a particular use. Various conventional methods for preparing the foam pads will be readily apparent to those skilled in the art.

In some embodiments, a thermally conductive pad can be used to form a heat management assembly in which the two side of the thermally conductive pad are in direct contact, respectively, with two heat transfer surfaces, a first heat transfer surface that is a heat generating surface, specifically an electronic device or component thereof, and a second heat transfer surface that is part of a thermal dissipation element, for example, a heat sink or circuit board. Since the pad is compressible, it can readily conform to the first and second heat transfer surfaces, whether these surfaces are regular or irregular in shape. As the pad is compressed, the thermal conductivity increases, thereby enhancing the heat transfer from the electronic device, or component thereof, to the heat sink. Thus, the desired thermal management for a particular application can be provided so that temperature-sensitive elements in an electronic device can be maintained within a prescribed operating temperature, thus, system failure or performance degradation of the device, due to heat generation, can be avoided.

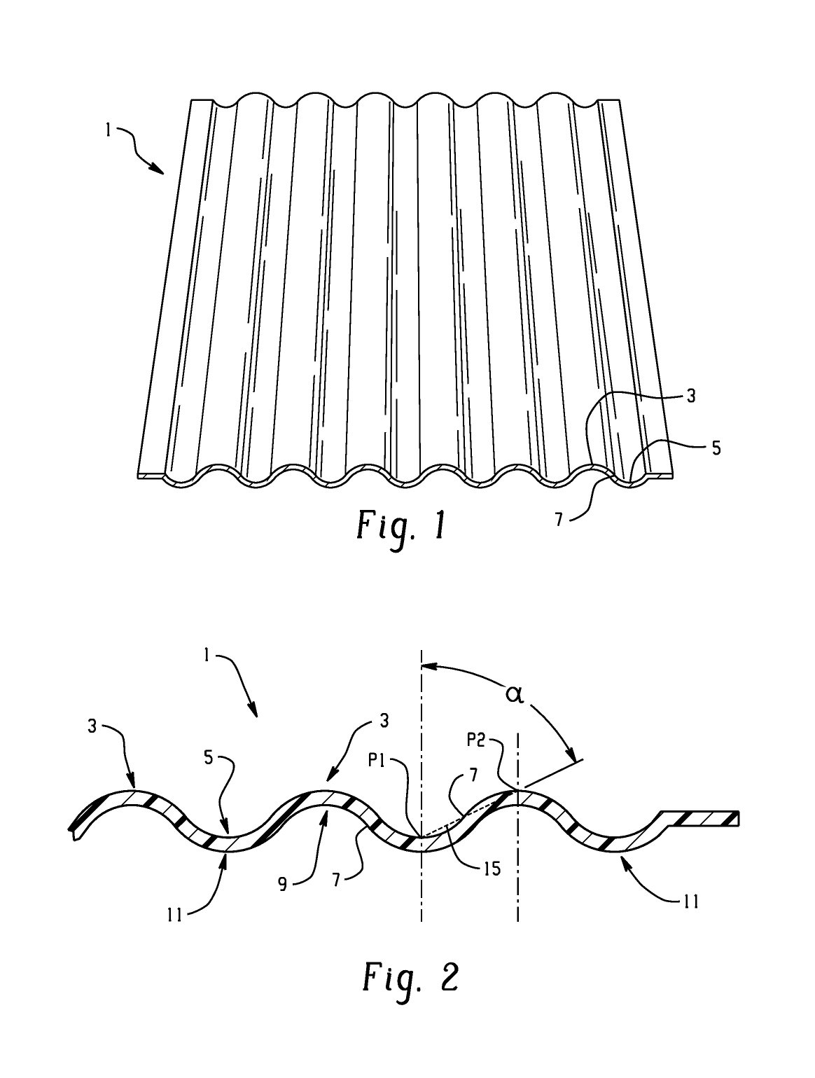

As can be seen in the embodiment of FIGS. 1 and 2 (in perspective view and cross-sectional view, respectively), a corrugated elastomeric sheet 1 comprises, in top plan view, a plurality of rows of alternating front ridges 3 and front grooves 5. As evident in the figures, each front ridge is joined to an adjacent front groove by a common side 7 connecting the front ridge to a front groove.

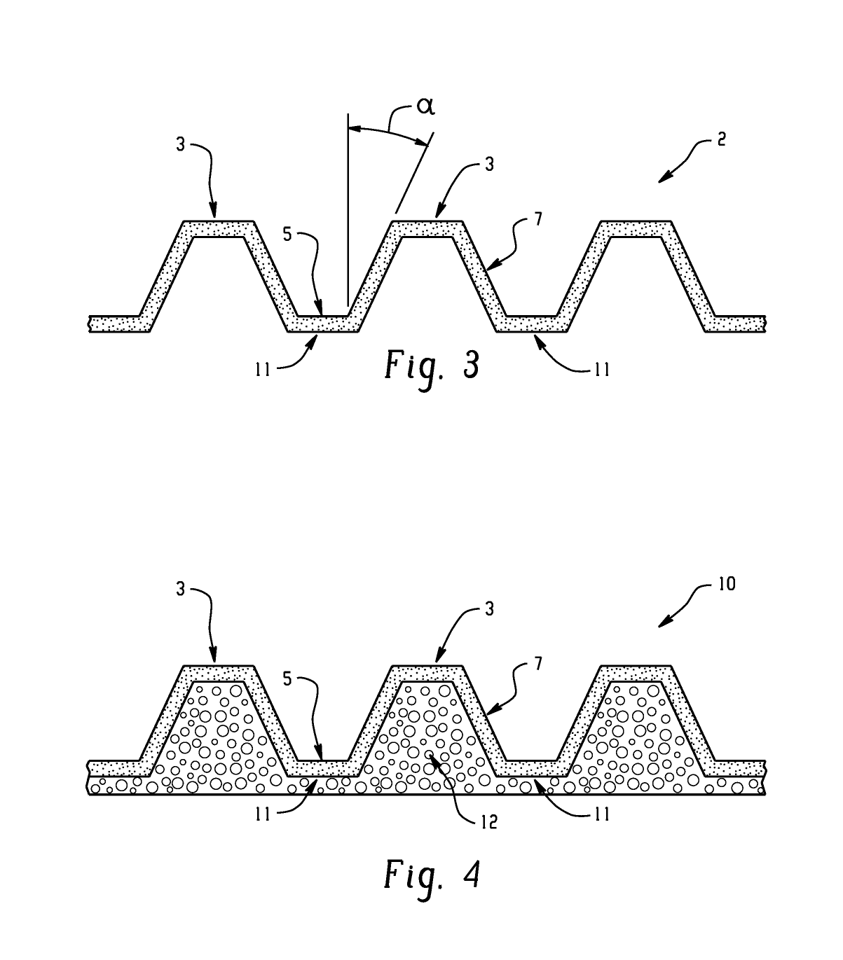

As best shown in FIG. 2, the corrugated elastomeric sheet, in cross-sectional view through its thickness, forms rows of alternating back ridges 11, a common side 7 connects each back ridge 11 to an adjacent back groove 9. In FIG. 3, the back grooves 9 are formed on the reverse side of the sheet portion forming front ridges 3, and back ridges 11 are formed on the reverse side of the sheet portion forming front grooves 5.

In FIG. 2, the common sides joining front ridges to front grooves in the corrugated elastomeric sheet can resiliently form an angle β (beta) of less than 90 degrees to the horizontal (x-direction in cross-section), specifically less than 75 degrees, more specifically an angle of 10 to 70 degrees, most specifically 25 to 65 degrees. The angle β can be determined by forming vertical lines (perpendicular to the thickness) passing through the peak of a ridge and the bottom of an adjacent ridge and then determining the bottom angle formed by the hypotenuse of the triangle which has a vertical distance extending from the bottom of the groove P1 and the top of the adjacent ridge P2. This angle, referred to as angle β will be equal to angle of 90 degrees minus angle α (alpha), in which angle α is the top angle formed by the hypotenuse.

The corrugated elastomeric sheet material itself can have a porosity of 0 to 25%, specifically 0 to 15%, more specifically, 0 to 10%, by using a foamed elastomeric composition, as described below. In an embodiment it is not foamed.

The shape of the corrugated elastomeric sheet can vary. Among various shapes, FIG. 3 shows a cross-sectional side-view of a corrugated elastomeric pad according to an embodiment in which corrugation comprises flat surfaces areas, as compared to the rounded or curved surfaces of the corrugation shown in FIG. 2. The top surfaces of the ridges or the bottom surfaces of the grooves, or both, can be flat, rounded, pointed, irregular, or otherwise shaped. Similarly, sides joining the tops of the ridges and bottoms of the grooves, can be straight or variously curved. The numbering of parts in FIG. 3 similarly corresponds to the numbering of parts in FIG. 2. In this embodiment the tringle formed from the vertical lines extend a horizontal distance from closest bottom point of the grove to the closest top point of the adjacent top ridge and, hence, the line forming angle β has the same slope as the side wall of the corrugated elastomeric sheet.

The ridges and grooves, on front or back surfaces of a corrugated elastomeric sheet, can be independently shaped. In some embodiment, only a portion of the thermally conductive material is corrugated.

The corrugated elastomeric sheet or pad, exemplified in FIG. 2 or 3, when compressed between two heat transfer surfaces can flatten to at least some extent and the angle β can decrease to at least some extent, as the thickness of the corrugated elastomeric pad decreases in the z-direction under compression. The angle β can potentially decrease to an angle as low as 0-20 degrees, wherein at zero degrees the corrugated elastomeric pad is essentially flat, although providing contact pressure against a heat transfer surface due to the resilience of the pad based on the compressible composition and original corrugated structure before compression. In some embodiments, top or bottom surface of a groove or ridge that is flat can aid thermal transfer in some embodiments by providing increased direct contact. Thermal transfer can also depend on such factors as the angle β, the thickness of the material, and filler loading.

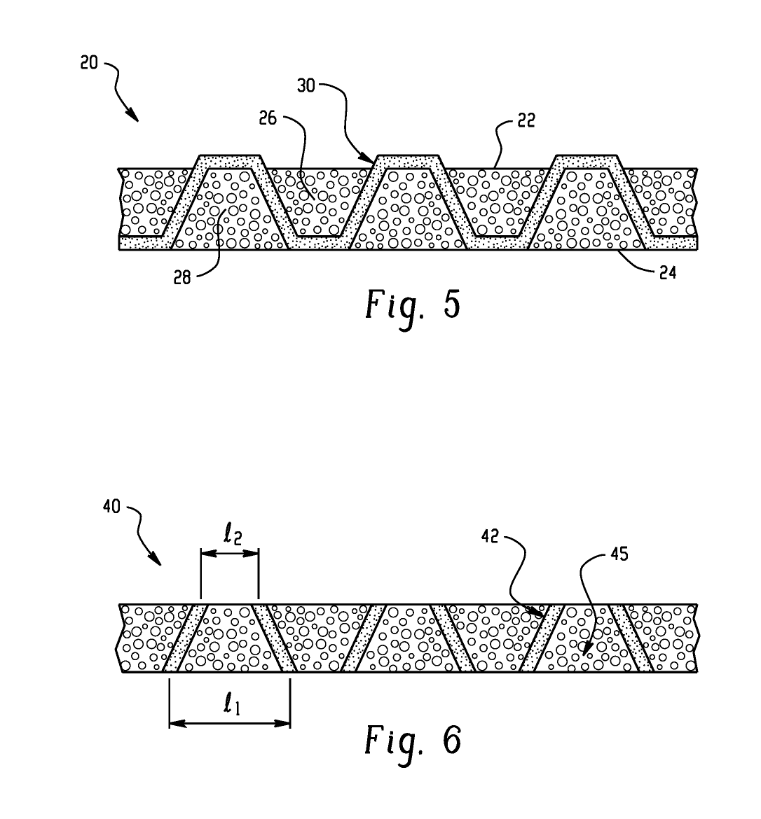

In some embodiments, a thermally conductive pad can comprise a corrugated elastomeric sheet at least partially embedded in a foam material or covered a by layer of foam material. FIG. 4 shows a cross-sectional view of a corrugated elastomeric sheet 10 in which a layer of polymeric foam 12 covers a back surface of the sheet. In FIG. 5, the bottom surface 11 of the back ridges of the corrugated elastomeric sheet are covered by the polymeric foam material. In other embodiments the bottom surface 11 can be exposed and the grooves at least partially filled with polymeric foam material.

In still other embodiments, a corrugated elastomeric sheet can be fully embedded in a polymer foam material or sheet, wherein the top surface of the ridges and bottom surfaces of the grooves on both the front and back surfaces are beneath the front and back surfaces of the polymer foam material, specifically near the surface. Alternatively, the entire corrugated elastomeric sheet except the flat exposed surfaces of ridges on the front or back surfaces. Or both can be covered by the foam material or sheet, so that exposed surfaces of the corrugated elastomeric sheet can be in direct contact with a heat source or heat sink. In still other embodiments, only one of the front and back surfaces of the corrugated elastomeric pad is covered by the polymeric foam material. The foam material, in any of the embodiments using the same, can have a porosity of greater than 10% (for example, air), specifically 10 to 90%, more specifically 50 to 90% porosity, most specifically 70 to 90% porosity. In some embodiments, the porosity, or volume fraction, of the foam material is greater than that of any optional porosity, if present, in the corrugated elastomeric pad associated with the foam material, for example embedded therein. On the other hand, the composition of the foam material can comprise a volume percent, if any, of thermally conductive filler that is lower than in the corrugated elastomeric sheet. Thus, the material comprising the corrugated elastomeric sheet can provide greater thermal conductivity, intrinsically, than the material forming the polymeric foam material optionally used to cover or embed the corrugated elastomeric sheet or portion thereof.

Another embodiment of a thermally conductive pad 20 is shown in FIG. 5, in which front ridges or back ridges, or both, of the corrugated elastomeric sheet extend beyond, respectively, the front surface 22 or back surface 24, or both, of a sheet of foam polymer material. Thus, the front grooves 26 or back grooves 28, or both, of a corrugated elastomeric sheet 30 can be at least partially filled (or completely filled), respectively, by a polymeric foam material, thereby forming a flat sheet that can at least partially embed the corrugated elastomeric sheet.

In some embodiments, a void space/volume can be present under front ridge surfaces of the corrugated filled elastomeric sheet, between the top of a front ridge and the front surface of the sheet of foam material, which void space can be designed to decrease space for increased compressibility. In other embodiments, such a void space can be present under both front ridges and back ridges. In still other embodiments, void spaces between a surface of a corrugated elastomeric sheet and a surface of foam material, can be entirely absent. In still other embodiments, foam material on opposite sides of the corrugated elastomeric sheet can have misaligned front and back surfaces, for example, by independently applying foamed material to each of the two sides of the corrugated elastomeric sheet.

The compressible thermally conductive material of FIG. 5, when compressed between two heat transfer surfaces (not shown), can flatten to some extent and, as the thickness of the corrugated elastomer pad decreases in the z-direction (in cross-sectional thickness), the angle β (beta) can decreases to the horizontal. Also, any void space in the thermally conductive pad, as discussed above, can decrease or even disappear in what compressed.

As indicated above, with respect to the shape of the compressible corrugated elastomeric sheet in cross-sectional view, each front or back ridge or groove can be independently shaped and can form a point, line segment, or other shape. Whereas a flattened ridge top surface can provide increased direct contact with a flat heat transfer surface, a rounded top surface of a corrugated elastomeric sheet (as in a sine wave) can be designed to form a flat surface under compression. In some embodiments, both the top surfaces of the front ridges and the top surfaces of the back ridges, in cross-sectional view, form parallel flat surfaces capable of adjacent contact, respectively, with a heat source and a heat sink.

In some embodiments, a compressible thermally conductive pad can be derived from an elastomeric corrugated sheet, having opposed upper and lower corrugated surfaces, embedded in a polymeric foam material, wherein a top portion of the ridges or bottom portion of grooves, or both, have been removed. In such embodiments, the thermally conductive pad comprises, in a cross-sectional view through its thickness, a plurality of columns formed from filled elastomeric material, which columns extend from a lower surface portion of the material to an upper surface or portion of the material, and wherein consecutive columns in an x-direction slant at an angle in alternate directions from the a perpendicular line joining the top and bottom surfaces.

FIG. 6 shows a cross-sectional side view of a corrugated elastomeric pad according to such an embodiment, in which a top portion of each of a plurality of front ridges and a bottom portion of each of a plurality of front grooves is absent. (In other embodiments, only one of the two, either a top portion of each of a plurality of front ridges or a bottom portion of each of a plurality of front grooves, may be absent such that a series of “U” shapes, or the like, can be seen in cross-section.)

As shown in FIG. 6, the thermally conductive pad 40 forms, in cross-section, a plurality of columns 42 of filled elastomeric material embedded in polymeric foamed material 45, wherein each of said columns are adjacent to two other columns and slant in a direction towards one of the two adjacent columns and in the direction away from the other of the two adjacent columns such that the tops of two adjacent columns alternate, in cross-sectional view of the pad along its length, between being slanted towards each other and being slanted away from each other; and wherein the tops of adjacent columns that slant towards each other alternate with the bottoms of adjacent columns slanting towards each other. During compression of the thermally conductive material, the angle β (to the x-axis) of each column can decrease, and the distance between the tops of adjacent columns (distance l₁ in FIG. 6), where slanted away from each other, can increase. Thus, referring to FIG. 6, a compressible thermally conductive material 40 is shown in which columns (which form walls in plain view) of an elastomeric material 42 are embedded in a foam material 45, wherein a distance l₂ separates the tops of adjacent columns that slant towards each other and a distance l₁ separates the bottoms of adjacent columns that slant away from each other. Under compression, the distance between the tops of adjacent columns (distance l₂ in FIG. 6), where slanted towards each other, can decrease or even disappear when the tops of adjacent columns touch.

In another aspect, the embodiment shown in FIG. 6 can optionally be made by removing either a top surface or a bottom surface, or both, for example, by abrasion, grinding, or other conventional technique. However, other methods of manufacture, not involving a corrugated sheet, may be envisioned, in which each wall is separately inserted into a foam material prior to the foam material being cured.

In some embodiments, a method of making a compressible thermally conductive material comprises embedding a corrugated elastomeric sheet material in a foamed polymeric material to form an intermediate sheet material. The intermediate sheet material can be a fully or partially embedded corrugated sheet material as described above. In a subsequent step, a top or bottom surface layer, or both, of the intermediate sheet material can be removed so that, in cross-sectional view, an upper portion of the front ridges or an upper portion of the back ridges, or both, are absent. Consequently, the final thermally conductive material, in cross-sectional view through its thickness, forms a plurality of columns made from a filled elastomeric material, which columns extend from the lower surface, or surface portion, to an upper surface, or surface portion, of the pad, and wherein consecutive adjacent columns slant in alternate directions from a perpendicular line joining the top and bottom surfaces. Specifically, each of said columns can be adjacent to two other columns and slant in a direction towards one of the two adjacent columns and in the direction away from the other of the two adjacent columns such that the tops of two adjacent columns alternate, in cross-sectional view of the materials along its x-axis, between being slanted towards each other and being slanted away from each other. In other words, the tops of adjacent columns which slant towards each other alternate with the bottoms of adjacent columns which slant towards each other. As indicated below, some embodiments can comprise two adjacent columns connected to form a “U-like” shape by removing a surface portion of only one of either a front or back portion of the embedded corrugated elastomeric sheet.

In some embodiments, the composition of the corrugated elastomeric sheet, specifically in any of the above-described embodiments, can comprise primarily polyurethane or silicone, specifically greater than 50 wt. % up to 100 wt. % of the total polymer in the composition. In particular, the polymeric composition of the corrugated elastomeric material can comprise at least 60% polyurethane or silicone optionally blended with another polymer, for example silicone, polyolefin, polyester, polyamide, fluorinated polymer, polyalkylene oxide, polyvinyl alcohol, ionomer, cellulose acetate, polystyrene, or a combination comprising at least one of the foregoing. Specifically, the composition of the corrugated elastomeric material comprises a heat cured silicone composition, for example a two-part LSR (liquid silicone rubber) or gel, as described in detail below.

The polymeric matrix material in the corrugated filled elastomeric sheet can be non-foamed or foamed to some extent, up to 25% porosity, specifically 0 to 10%, more specifically 0 to 5%. In an embodiment, the material is not foamed. Higher porosity can be undesirable because it lowers the thermal conductivity of the corrugated structure.

The composition of the corrugated elastomeric sheet comprises filler material, that is, a corrugated elastomeric sheet is a filled material. In particular, the corrugated elastomeric sheet can comprise particles of thermally conductive filler having a thermal conductivity of 25 W/m-K to 1000 W/m-K. In some embodiments, the particulate filler can be a metal or a non-metal oxide, nitride, carbide, or boride. The particulate filler can also be carbon (e.g., graphite), a metal, or a combination comprising at least one of the foregoing, specifically particles of boron nitride or graphite, or both, inclusive of graphite fibers.

A thermally conductive composition for forming the corrugated elastomeric sheet can comprise thermally conductive particles, in a polymer matrix, in a proportion sufficient to provide the thermal conductivity desired for the intended application. Generally the loading can be in an amount of from 10% to 90% by weight, specifically 15% to 80, more specifically 20 to 70%, most specifically 20 to 60% by weight of thermally conductive filler particles. Specifically, the particles can be present in an amount of 25 to 45%, specifically 30 to 40%, based on the weight of the composition.

In an embodiment, the particles can advantageously be incorporated into a silicone or polyurethane composition using any number of conventional techniques well known in the art, such as by compounding, blending, and the like.

The size and shape of the filler particles is not critical. In this regard, the filler particles can be of any particulate shape, including solid or hollow spherical or microspherical flakes, platelets, irregular or fibrous shapes, specifically a powder for obtaining uniform dispersal and homogeneous mechanical and thermal properties. The particle size or distribution of the filler typically can range from between 0.01 mil to 10 mil, specifically 10 to 500 micrometers, more specifically 30 to 300 micrometers, most specifically 50 to 200 micrometers (μm), which refers to a mean diameter or equivalent diameter as best determined by standard laser particle measurement.

Thermally-conductive particulate fillers can include, more particularly, boron nitride (BN), titanium diboride, aluminum nitride, silicon carbide, graphite, metals such as silver, aluminum, and copper, metal oxides such as aluminum oxide, magnesium oxide, zinc oxide, beryllium oxide, antimony oxide, and mixtures thereof. Ceramic materials are included. Such fillers characteristically exhibit a thermal conductivity of at least 20 W/m-K. For reasons of economy, an aluminum oxide, i.e., alumina, can be used, while for reasons of improved thermal conductivity a boron nitride may be preferred. Specifically, the filler can comprise BN particles.

In an embodiment, either or both the corrugated elastomeric sheet and the optional polymeric foam material for embedding the corrugated elastomeric sheet can comprise a polyurethane matrix polymer, optionally foamed, such as an open cell, low modulus polyurethane foam, which can have an average cell size of 50 to 250 μm, as may be measured, for example, in accordance with ASTM D 3574-95, a density of between 5-30 lbs/ft³ (80 to 481 kg/m³), specifically 6 to 25 lbs/ft³, a compression set of less than 10%, and a force-deflection of between 1-9 psi (7-63 kPa). Such materials are marketed under the name Poron®4700 by the Rogers Corporation, Woodstock, Conn. PORON® foams have been formulated to provide an excellent range of properties, including compression set resistance. Foams with good compression set resistance provide cushioning, and maintain their original shape or thickness under loads for extended periods.

Other polymers for use in the associated foam material or corrugated elastomeric sheet, at least in part or in blends, can be a wide variety of thermoplastic or thermosetting polymers. Examples of thermoplastic polymers that can be used include polyacetals, polyacrylics, styrene acrylonitrile, polyolefins, acrylonitrile-butadiene-styrene, polycarbonates, polystyrenes, polyethylene terephthalates, polybutylene terephthalates, polyamides such as, but not limited to Nylon 6, Nylon 6,6, Nylon 6,10, Nylon 6,12, Nylon 11 or Nylon 12, polyamideimides, polyarylates, polyurethanes, ethylene propylene rubbers (EPR), polyarylsulfones, polyethersulfones, polyphenylene sulfides, polyvinyl chlorides, polysulfones, polyetherimides, polytetrafluoroethylenes, fluorinated ethylene propylenes, polychlorotrifluoroethylenes, polyvinylidene fluorides, polyvinyl fluorides, polyetherketones, polyether etherketones, polyether ketone ketones, and the like, or a combination comprising at least one of the foregoing.

Examples of polymeric thermosetting resins that can be used to make the corrugated elastomeric sheet or associated foam material can include polyurethanes, epoxies, phenolics, polyesters, polyamides, silicones, and the like, or a combination comprising at least one of the foregoing. Blends of thermosetting polymers as well as blends of thermoplastic with thermosetting resins can be used.

A polyurethane foam can be manufactured mechanically or chemically, e.g., by mechanically frothing, chemical blowing, as well as combinations comprising at least one of the foregoing. For example, a polymer mixture can be mechanically frothed followed by forming into sheets by casting, after which the foams can be cured.

In general, polyurethane foams can be formed from reactive compositions comprising an organic isocyanate component reactive with an active hydrogen-containing component(s), a surfactant, and a catalyst. The organic isocyanate components used in the preparation of polyurethane foams generally comprises polyisocyanates having the general formula Q(NCO)ᵢ, wherein “i” is an integer having an average value of two or greater than two, and Q is an organic radical having a valence of “i”. Q can be a substituted or unsubstituted hydrocarbon group (e.g., an alkane or an aromatic group of the appropriate valency). Q can be a group having the formula Q¹-Z-Q¹ wherein Q¹ is an alkylene or arylene group and Z is —O—, —O-Q¹-S, —CO—, —S—, —S-Q¹-S—, —SO— or —SO₂—. Exemplary isocyanates include hexamethylene diisocyanate, 1,8-diisocyanato-p-methane, xylyl diisocyanate, diisocyanatocyclohexane, phenylene diisocyanates, tolylene diisocyanates, including 2,4-tolylene diisocyanate, 2,6-tolylene diisocyanate, and crude tolylene diisocyanate, bis(4-isocyanatophenyl)methane, chlorophenylene diisocyanates, diphenylmethane-4,4′-diisocyanate (also known as 4,4′-diphenyl methane diisocyanate, or MDI) and adducts thereof, naphthalene-1,5-diisocyanate, triphenylmethane-4,4′,4″-triisocyanate, isopropylbenzene-alpha-4-diisocyanate, polymeric isocyanates such as polymethylene polyphenylisocyanate, and combinations comprising at least one of the foregoing isocyanates.

Q can also represent a polyurethane radical having a valence of “i”, in which case Q(NCO)ᵢ is a composition known as a prepolymer. Such prepolymers are formed by reacting a stoichiometric excess of a polyisocyanate as set forth hereinbefore and hereinafter with an active hydrogen-containing component as set forth hereinafter, especially the polyhydroxyl-containing materials or polyols described below. Usually, for example, the polyisocyanate is employed in proportions of 30% to 200% stoichiometric excess, the stoichiometry being based upon equivalents of isocyanate group per equivalent of hydroxyl in the polyol. The amount of polyisocyanate employed will vary slightly depending upon the nature of the polyurethane being prepared.

The active hydrogen-containing component can comprise polyether polyols and polyester polyols. Exemplary polyester polyols are inclusive of polycondensation products of polyols with dicarboxylic acids or ester-forming derivatives thereof (such as anhydrides, esters and halides), polylactone polyols obtainable by ring-opening polymerization of lactones in the presence of polyols, polycarbonate polyols obtainable by reaction of carbonate diesters with polyols, and castor oil polyols. Exemplary dicarboxylic acids and derivatives of dicarboxylic acids which are useful for producing polycondensation polyester polyols are aliphatic or cycloaliphatic dicarboxylic acids such as glutaric, adipic, sebacic, fumaric and maleic acids; dimeric acids; aromatic dicarboxylic acids such as phthalic, isophthalic and terephthalic acids; tribasic or higher functional polycarboxylic acids such as pyromellitic acid; as well as anhydrides and second alkyl esters, such as maleic anhydride, phthalic anhydride and dimethyl terephthalate.

Additional active hydrogen-containing components are the polymers of cyclic esters. The preparation of cyclic ester polymers from at least one cyclic ester monomer is well documented in the patent literature as exemplified by U.S. Pat. Nos. 3,021,309 through 3,021,317; 3,169,945; and 2,962,524. Exemplary cyclic ester monomers include δ-valerolactone; ε-caprolactone; zeta-enantholactone; and the monoalkyl-valerolactones (e.g., the monomethyl-, monoethyl-, and monohexyl-valerolactones). In general the polyester polyol can comprise caprolactone based polyester polyols, aromatic polyester polyols, ethylene glycol adipate based polyols, and combinations comprising at least one of the foregoing polyester polyols, and especially polyester polyols made from ε-caprolactones, adipic acid, phthalic anhydride, terephthalic acid or dimethyl esters of terephthalic acid.

The polyether polyols are obtained by the chemical addition of alkylene oxides (such as ethylene oxide, propylene oxide, and so forth, as well as combinations comprising at least one of the foregoing), to water or polyhydric organic components (such as ethylene glycol, propylene glycol, trimethylene glycol, 1,2-butylene glycol, 1,3-butanediol, 1,4-butanediol, 1,5-pentanediol, 1,2-hexylene glycol, 1,10-decanediol, 1,2-cyclohexanediol, 2-butene-1,4-diol, 3-cyclohexene-1,1-dimethanol, 4-methyl-3-cyclohexene-1,1-dimethanol, 3-methylene-1,5-pentanediol, diethylene glycol, (2-hydroxyethoxy)-1-propanol, 4-(2-hydroxyethoxy)-1-butanol, 5-(2-hydroxypropoxy)-1-pentanol, 1-(2-hydroxymethoxy)-2-hexanol, 1-(2-hydroxypropoxy)-2-octanol, 3-allyloxy-1,5-pentanediol, 2-allyloxymethyl-2-methyl-1,3-propanediol, [4,4-pentyloxy)-methyl]-1,3-propanediol, 3-(o-propenylphenoxy)-1,2-propanediol, 2,2′-diisopropylidenebis(p-phenyleneoxy)diethanol, glycerol, 1,2,6-hexanetriol, 1,1,1-trimethylolethane, 1,1,1-trimethylolpropane, 3-(2-hydroxyethoxy)-1,2-propanediol, 3-(2-hydroxypropoxy)-1,2-propanediol, 2,4-dimethyl-2-(2-hydroxyethoxy)-methylpentanediol-1,5; 1,1,1-tris[2-hydroxyethoxy) methyl]-ethane, 1,1,1-tris[2-hydroxypropoxy)-methyl] propane, diethylene glycol, dipropylene glycol, pentaerythritol, sorbitol, sucrose, lactose, alpha-methylglucoside, alpha-hydroxyalkylglucoside, novolac resins, phosphoric acid, benzenephosphoric acid, polyphosphoric acids such as tripolyphosphoric acid and tetrapolyphosphoric acid, ternary condensation products, and so forth, as well as combinations comprising at least one of the foregoing). The alkylene oxides employed in producing polyoxyalkylene polyols normally have 2 to 4 carbon atoms. Propylene oxide and mixtures of propylene oxide with ethylene oxide are preferred. The polyols listed above can be used per se as the active hydrogen component.

A useful class of polyether polyols is represented generally by the following formula: R[(OCHₙH₂ₙ)_{z}OH]ₐ wherein R is hydrogen or a polyvalent hydrocarbon radical; “a” is an integer equal to the valence of R, “n” in each occurrence is an integer of 2 to 4 inclusive (specifically 3), and “z” in each occurrence is an integer having a value of 2 to 200, or, more specifically, 15 to 100. Desirably, the polyether polyol comprises a mixture of one or more of dipropylene glycol, 1,4-butanediol, and 2-methyl-1,3-propanediol, and so forth.

Another type of active hydrogen-containing materials that can be used is polymer polyol compositions obtained by polymerizing ethylenically unsaturated monomers in a polyol as described in U.S. Pat. No. 3,383,351. Exemplary monomers for producing such compositions include acrylonitrile, vinyl chloride, styrene, butadiene, vinylidene chloride, and other ethylenically unsaturated monomers. The polymer polyol compositions can contain 1 weight percent (wt. %) to 70 wt. %, or, more specifically, 5 wt. % to 50 wt. %, and even more specifically, 10 wt. % to 40 wt. % monomer polymerized in the polyol, where the weight percent is based on the total weight of polyol. Such compositions are conveniently prepared by polymerizing the monomers in the selected polyol at a temperature of 40 to 150° C. in the presence of a free radical polymerization catalyst such as peroxides, persulfates, percarbonate, perborates, azo compounds, and combinations comprising at least one of the foregoing.

The active hydrogen-containing component can also contain polyhydroxyl-containing compounds, such as hydroxyl-terminated polyhydrocarbons (U.S. Pat. No. 2,877,212); hydroxyl-terminated polyformals (U.S. Pat. No. 2,870,097); fatty acid triglycerides (U.S. Pat. Nos. 2,833,730 and 2,878,601); hydroxyl-terminated polyesters (U.S. Pat. Nos. 2,698,838, 2,921,915, 2,591,884, 2,866,762, 2,850,476, 2,602,783, 2,729,618, 2,779,689, 2,811,493, 2,621,166 and 3,169,945); hydroxymethyl-terminated perfluoromethylenes (U.S. Pat. Nos. 2,911,390 and 2,902,473); hydroxyl-terminated polyalkylene ether glycols (U.S. Pat. No. 2,808,391; British Pat. No. 733,624); hydroxyl-terminated polyalkylenearylene ether glycols (U.S. Pat. No. 2,808,391); and hydroxyl-terminated polyalkylene ether triols (U.S. Pat. No. 2,866,774).

In an embodiment, the reactive composition for producing foam polymer can be substantially in accordance with Japanese Patent Publication No. Sho 53-8735. The polyol desirably used has a repeated unit of each of PO (propylene oxide) or PTMG (tetrahydrofuran subjected to ring-opening polymerization), or the like. In a specific embodiment, the amount of EO (ethylene oxide; (CH₂CH₂O)ₙ) is minimized in order to improve the hygroscopic properties of the foam.

The polyols can have hydroxyl numbers that vary over a wide range. In general, the hydroxyl numbers of the polyols, including other cross-linking additives, if used, can be 28 to 1,000, and higher, or, more specifically, 100 to 800. The hydroxyl number is defined as the number of milligrams of potassium hydroxide required for the complete neutralization of the hydrolysis product of the fully acetylated derivative prepared from 1 gram of polyol or mixtures of polyols with or without other cross-linking additives. The hydroxyl number can also be defined by the equation:

$$OH = \frac{56.1 \times 1000 \times f}{{M}_{W}}$$

wherein: OH is the hydroxyl number of the polyol,
f is the average functionality, that is the average number of hydroxyl groups per molecule of polyol, and
M_{W} is the average molecular weight of the polyol.

As noted above, the foams can be chemically blown or physically blown (e.g., mechanically frothed). When used, a wide variety of blowing agent(s) can be employed in the reactive compositions, including chemical or physical blowing agents. Chemical blowing agents include, for example, water, and chemical compounds that decompose with a high gas yield under specified conditions, for example within a narrow temperature range. Desirably, the decomposition products do not effloresce or have a discoloring effect on the foam product. Exemplary chemical blowing agents include water, azoisobutyronitrile, azodicarbonamide (i.e. azo-bis-formamide) and barium azodicarboxylate; substituted hydrazines (e.g., diphenylsulfone-3,3′-disulfohydrazide, 4,4′-hydroxy-bis-(benzenesulfohydrazide), trihydrazinotriazine, and aryl-bis-(sulfohydrazide)); semicarbazides (e.g., p-tolylene sulfonyl semicarbazide an d4,4′-hydroxy-bis-(benzenesulfonyl semicarbazide)); triazoles (e.g., 5-morpholyl-1,2,3,4-thiatriazole); N-nitroso compounds (e.g., N,N′-dinitrosopentamethylene tetramine and N,N-dimethyl-N,N′-dinitrosophthalmide); benzoxazines (e.g., isatoic anhydride); as well as combinations comprising at least one of the foregoing, such as, sodium carbonate/citric acid mixtures.

The amount of blowing agents will vary depending on the agent and the desired foam density. In general, these blowing agents are used in an amount of 0.1 wt. % to 10 wt. %, based upon a total weight of the reactive composition. When water is employed as at least one of the blowing agent(s) (e.g., in an amount of 0.1 wt. % to 8 wt. % based upon the total weight of reactive composition), it is generally desirable to control the curing reaction by selectively employing catalysts.

Physical blowing agents can also (or alternatively) be used. These blowing agents can be a broad range of materials, including hydrocarbons, ethers, esters, (including partially halogenated hydrocarbons, ethers, and esters), and so forth, as well as combinations comprising at least one of the foregoing. As with the chemical blowing agents, the physical blowing agents are used in an amount sufficient to give the resultant foam the desired bulk density. The physical blowing agents can be used in an amount of 5 wt. % to 50 wt. % of the reactive composition, or, more specifically, 10 wt. % to 30 wt. %.

A number of the catalysts capable of catalyzing the reaction of the isocyanate component with the active hydrogen-containing component can be used in the foam preparation. Exemplary catalysts include phosphines; tertiary organic amines; organic and inorganic acid salts of, and organometallic derivatives of bismuth, lead, tin, iron, antimony, uranium, cadmium, cobalt, thorium, aluminum, mercury, zinc, nickel, cerium, molybdenum, vanadium, copper, manganese, and zirconium; as well as combinations comprising at least one of the foregoing.

A wide variety of surfactants can be used for purposes of stabilizing the polyurethane foam before it is cured, including mixtures of surfactants. Organosilicone surfactants are especially useful, such as a copolymer consisting essentially of SiO₂ (silicate) units and (CH₃)₃Si_{0.5} (trimethylsiloxy) units in a molar ratio of silicate to trimethylsiloxy units of 0.8:1 to 2.2:1, or, more specifically, 1:1 to 2.0:1.

In an embodiment, the foams can be produced by mechanically mixing the reactive composition (i.e., isocyanate component(s), active hydrogen-containing component(s), froth-stabilizing surfactant(s), catalyst(s), and any optional additive(s)) with a froth-forming gas in a predetermined amount. In one manner of proceeding, the components of the reactive composition are first mixed together and then subjected to mechanical frothing with air. Alternatively, the components can be added sequentially to the liquid phase during the mechanical frothing process. The gas phase of the froths can be air because of its cheapness and ready availability. However, if desired, other gases can be used that are gaseous at ambient conditions and that are substantially inert or non-reactive with all components of the liquid phase. Other gases include, for example, nitrogen, carbon dioxide, and fluorocarbons that are normally gaseous at ambient temperatures.

The inert gas is incorporated into the liquid phase by mechanical beating of the liquid phase in high shear equipment such as in a Hobart mixer or an Oakes mixer. The gas can be introduced under pressure or it can be drawn in from the overlying atmosphere by the beating or whipping action as in a Hobart mixer. The mechanical beating operation can be conducted at standard pressures, for example pressures of 100 pounds per square inch (psi) to 200 psi (689 kilopascals (kPa) to 1,379 kPa). Readily available mixing equipment can be used. The amount of inert gas beaten into the liquid phase is controlled by gas flow metering equipment to produce a froth of the desired density. The mechanical beating is conducted over an appropriate period to obtain the desired froth density, for example a few seconds in an Oakes mixer, or 3 to 30 minutes in a Hobart mixer. The froth as it emerges from the mechanical beating operation is substantially chemically stable and is structurally stable, but easily workable at ambient temperatures, e.g., 10° C. to 40° C.

Examples of silicone resins or foams that can be used to make the corrugated elastomeric sheet or associated foam material, for optionally embedding the corrugated elastomeric sheet, can include a polysiloxane polymer. In an embodiment, silicone foams are produced as a result of the reaction between water and hydride groups in a polysiloxane polymer precursor composition with the consequent liberation of hydrogen gas. This reaction is generally catalyzed by a noble metal, specifically a platinum catalyst. In an embodiment, the polysiloxane polymer has a viscosity of 100 to 1,000,000 poise at 25° C. and has chain substituents such as hydride, methyl, ethyl, propyl, vinyl, phenyl, and trifluoropropyl. The end groups on the polysiloxane polymer can be hydride, hydroxyl, vinyl, vinyl diorganosiloxy, alkoxy, acyloxy, allyl, oxime, aminoxy, isopropenoxy, epoxy, mercapto groups, or other known, reactive end groups. Suitable silicone foams can also be produced by using several polysiloxane polymers, each having different molecular weights (e.g., bimodal or trimodal molecular weight distributions) as long as the viscosity of the combination lies within the above specified values. It is also possible to have several polysiloxane base polymers with different functional or reactive groups in order to produce the desired foam. In an embodiment, the polysiloxane polymer comprises 0.2 moles of hydride (Si—H) groups per mole of water.

Depending upon the chemistry of the polysiloxane polymers used, a catalyst, generally platinum or a platinum-containing catalyst, can be used to catalyze the blowing and the curing reaction. The catalyst can be deposited onto an inert carrier, such as silica gel, alumina, or carbon black. In an embodiment, an unsupported catalyst, e.g., chloroplatinic acid, its hexahydrate form, its alkali metal salts, and its complexes with organic derivatives is used. Exemplary catalysts are the reaction products of chloroplatinic acid with vinylpolysiloxanes such as 1,3-divinyltetramethyldisiloxane, which are treated or otherwise with an alkaline agent to partly or completely remove the chlorine atoms; the reaction products of chloroplatinic acid with alcohols, ethers, and aldehydes; and platinum chelates and platinous chloride complexes with phosphines, phosphine oxides, and with olefins such as ethylene, propylene, and styrene. It can also be desirable, depending upon the chemistry of the polysiloxane polymers to use other catalysts such as dibutyl tin dilaurate in lieu of platinum based catalysts.

Physical or chemical blowing agents can be used to produce the silicone foam, including the physical and chemical blowing agents listed above for polyurethanes. Other examples of chemical blowing agents include benzyl alcohol, methanol, ethanol, isopropyl alcohol, butanediol, and silanols. In an embodiment, a combination of methods of blowing is used to obtain foams having desirable characteristics. For example, a physical blowing agent such as a chlorofluorocarbon can be added as a secondary blowing agent to a reactive mixture wherein the primary mode of blowing is the hydrogen released as the result of the reaction between water and hydride substituents on the polysiloxane.

In the production of silicone foams, the reactive components of the precursor composition can be stored in two packages, one containing the platinum catalyst and the other the polysiloxane polymer containing hydride groups, which prevents premature reaction. In another method of production, the polysiloxane polymer is introduced into an extruder along with the electrically conductive particles, water, physical blowing agents if necessary, and other desirable additives. The platinum catalyst can then be metered into the extruder to start the foaming and curing reaction. The optional use of physical blowing agents such as liquid carbon dioxide or supercritical carbon dioxide in conjunction with chemical blowing agents such as water can give rise to foam having much lower densities.

In another embodiment, a non-foamed thermally conductive composition for making the corrugated elastomeric sheet can be formed by the reaction of a precursor composition comprising a liquid silicone polymer, specifically comprising a polysiloxane having at least two alkenyl groups per molecule and a polysiloxane having at least two silicon-bonded hydrogen atoms, in a quantity effective to cure the composition, further in the presence of a catalyst. Suitable reactive silicone compositions are low durometer, two-package (for example, 1:1) liquid silicone rubber (LSR) or liquid injection molded (LIM) compositions. Because of their low inherent viscosity, the use of a low durometer LSR or LIM composition can facilitate the addition of higher filler quantities.

In an embodiment, an LSR or LIM system can be provided as two-part formulations suitable for mixing in ratios of 1:1 by volume. The “A” part of the formulation can comprise one or more polysiloxanes having two or more alkenyl groups. Suitable alkenyl groups are exemplified by vinyl, allyl, butenyl, pentenyl, hexenyl, and heptenyl, specifically vinyl. The alkenyl group can be bonded at the molecular chain terminals, in pendant positions on the molecular chain, or both. Other silicon-bonded organic groups in the polysiloxane having two or more alkenyl groups can be exemplified by substituted and unsubstituted monovalent hydrocarbon groups, for example, alkyl groups such as methyl, ethyl, propyl, butyl, pentyl, and hexyl; aryl groups such as phenyl, tolyl, and xylyl; aralkyl groups such as benzyl and phenethyl; and halogenated alkyl groups such as 3-chloropropyl and 3,3,3-trifluoropropyl. Exemplary substituents are methyl and phenyl groups.

The alkenyl-containing polysiloxane can have straight chain, partially branched straight chain, branched-chain, or network molecule structure, or can be a mixture of two or more selections from polysiloxanes with the exemplified molecular structures. The alkenyl-containing polysiloxane is exemplified by trimethylsiloxy-end blocked dimethylsiloxane-methylvinylsiloxane copolymers, trimethylsiloxy-endblocked methylvinylsiloxane-methylphenylsiloxane copolymers, trimethylsiloxy-end blocked dimethylsiloxane-methylvinylsiloxane-methylphenylsiloxane copolymers, dimethylvinylsiloxy-endblocked dimethylpolysiloxanes, dimethylvinylsiloxy-endblocked methylvinylpolysiloxanes, dimethylvinylsiloxy-endblocked methylvinylphenylsiloxanes, dimethylvinylsiloxy-endblocked dimethylvinylsiloxane-methylvinylsiloxane copolymers, dimethylvinylsiloxy-endblocked dimethylsiloxane-methylphenylsiloxane copolymers, dimethylvinylsiloxy-endblocked dimethylsiloxane-diphenylsiloxane copolymers, polysiloxane comprising R₃SiO_{1/2} and SiO_{4/2} units, polysiloxane comprising RSiO_{3/2} units, polysiloxane comprising the R₂SOi_{2/2} and RSiO_{3/2} units, polysiloxane comprising the R₂SOi_{2/2}, RSiO_{3/2} and SiO_{4/2} units, and a mixture of two or more of the preceding polysiloxanes. R represents substituted and unsubstituted monovalent hydrocarbon groups, for example, alkyl groups such as methyl, ethyl, propyl, butyl, pentyl, and hexyl; aryl groups such as phenyl, tolyl, and xylyl; aralkyl groups such as benzyl and phenethyl; and halogenated alkyl groups such as 3-chloropropyl and 3,3,3-trifluoropropyl, with the proviso that at least 2 of the R groups per molecule are alkenyl.

A “B” component of an LSR or LIM system can comprise one or more polysiloxanes that contain at least two silicon-bonded hydrogen atoms per molecule and has an extrusion rate of less than 500 g/minute. The hydrogen can be bonded at the molecular chain terminals, in pendant positions on the molecular chain, or both. Other silicon-bonded groups are organic groups exemplified by non-alkenyl, substituted and unsubstituted monovalent hydrocarbon groups, for example, alkyl groups such as methyl, ethyl, propyl, butyl, pentyl, and hexyl; aryl groups such as phenyl, tolyl, and xylyl; aralkyl groups such as benzyl and phenethyl; and halogenated alkyl groups such as 3-chloropropyl and 3,3,3-trifluoropropyl. Exemplary substituents are methyl and phenyl groups.

The hydrogen-containing polysiloxane component can have straight-chain, partially branched straight-chain, branched-chain, cyclic, network molecular structure, or can be a mixture of two or more selections from polysiloxanes with the exemplified molecular structures. The hydrogen-containing polysiloxane is exemplified by trimethylsiloxy-endblocked methylhydrogenpolysiloxanes, trimethylsiloxy-endblocked dimethylsiloxane-methylhydrogensiloxane copolymers, trimethylsiloxy-endblocked methylhydrogensiloxane-methylphenylsiloxane copolymers, trimethylsiloxy-endblocked dimethylsiloxane-methylhydrogensiloxane-methylphenylsiloxane copolymers, dimethylhydrogensiloxy-endblocked dimethylpolysiloxanes, dimethylhydrogensiloxy-endblocked methylhydrogenpolysiloxanes, dimethylhydrogensiloxy-endblocked dimethylsiloxanes-methylhydrogensiloxane copolymers, dimethylhydrogensiloxy-endblocked dimethylsiloxane-methylphenylsiloxane copolymers, and dimethylhydrogensiloxy-endblocked methylphenylpolysiloxanes.

The hydrogen-containing polysiloxane component is added in an amount sufficient to cure the composition, specifically in a quantity of 0.5 to 10 silicon-bonded hydrogen atoms per alkenyl group in the alkenyl-containing polysiloxane.

The silicone composition further comprises, generally as part of Component “A,” a catalyst such as platinum to accelerate the cure. Platinum and platinum compounds known as hydrosilylation-reaction catalysts can be used, for example platinum black, platinum-on-alumina powder, platinum-on-silica powder, platinum-on-carbon powder, chloroplatinic acid, alcohol solutions of chloroplatinic acid platinum-olefin complexes, platinum-alkenylsiloxane complexes and the catalysts afforded by the microparticulation of the dispersion of a platinum addition-reaction catalyst, as described above, in a thermoplastic resin such as methyl methacrylate, polycarbonate, polystyrene, silicone, and the like. Mixtures of catalysts can also be used. A quantity of catalyst effective to cure the present composition is generally from 0.1 to 1,000 parts per million (by weight) of platinum metal based on the combined amounts of alkenyl and hydrogen components.

Reactive polysiloxane fluids co-cure with the alkenyl-containing polysiloxane and the polysiloxane having at least two silicon-bonded hydrogen atoms, and therefore can themselves contain alkenyl groups or silicon-bonded hydrogen groups. Such compounds can have the same structures as described above in connection with the alkenyl-containing polysiloxane and the polysiloxane having at least two silicon-bonded hydrogen atoms, but in addition have a viscosity of less than or equal to 1000 centipoise (cps), specifically less than or equal to 750 cps, more specifically less than or equal to 600 cps, and most specifically less than or equal to 500 cps. In an embodiment, the reactive polysiloxane fluids have a boiling point greater than the curing temperature of the addition cure reaction.

In addition to the above-mentioned thermally conductive fillers in the formulation of the corrugated elastomeric sheet and optional associated form material, other types of filler additives can be added, for example to a polyurethane froth mixture in the manufacture thereof. For example, non-thermally conductive fillers (alumina trihydrate, silica, talc, calcium carbonate, clay, and so forth), pigments (for example titanium dioxide and iron oxide), and so forth, as well as combinations can also be used.

Still other additives known for use in the manufacture of the corrugated elastomeric sheet or optional associated foam materials for embedding or supporting the corrugated elastomeric sheet can be present in the foam composition. For example, suitable flame retardants include, but not limited to metal hydroxide containing aluminum, magnesium, zinc, boron, calcium, nickel, cobalt, tin, molybdenum, copper, iron, titanium, or a combination thereof, for example aluminum trihydroxide, magnesium hydroxide, calcium hydroxide, iron hydroxide, and the like; a metal oxide such as antimony oxide, antimony trioxide, antimony pentoxide, iron oxide, titanium oxide, manganese oxide, magnesium oxide, zirconium oxide, zinc oxide, molybdenum oxide, cobalt oxide, bismuth oxide, chromium oxide, tin oxide, nickel oxide, copper oxide, tungsten oxide, and the like; metal borates such as zinc borate, zinc metaborate, barium metaborate, and the like; metal carbonates such as zinc carbonate, magnesium carbonate, calcium carbonate, barium carbonate, and the like; melamine cyanurate, melamine phosphate, and the like; carbon black, expandable graphite flakes (for example those available from GrafTech International, Ltd. under the tradename GRAFGUARD), and the like; nanoclays; and brominated compounds. Exemplary flame retardant materials are magnesium hydroxides, nanoclays, and brominated compounds. In an embodiment, flame retardance of the polymer foam meets certain Underwriter's Laboratories (UL) standards for flame retardance. For example, the polymer foam has a rating of V-0 under UL Standard 94.

Still other additives that can be present include dyes, antioxidants, ultraviolet (UV) stabilizers, catalysts for cure of the polymer, crosslinking agents, and the like, as well as combinations comprising at least one of the foregoing additives. Using the above-described polymer compositions, a corrugated elastomeric sheet can be molded or extruded into shape, as will be appreciated by the skilled artisan, using conventional molding or extrusion techniques. After the composition (for example, polyurethane or silicone foam as described above) is at least partially cured, it can be passed to a cooling zone where it is cooled by any suitable cooling device such as fans. Where appropriate, the material can be taken up on a roll for later use. In such a production mode, the length of the sheet can be up to 5 meters or more.

In some embodiments, a compressible thermally conductive pad can be made by applying a polymeric foam material, optionally comprising particles of thermally conductive particulate filler, to the surface of a corrugated elastomeric material in a conventional counter top lab coater. The polymeric foam material, for example a reactive silicone system in which the filler is dispersed, can be poured over the corrugated elastomeric sheet and hand casted over a set gap. The product can then be cured in an oven at an elevated temperature for an appropriate time, for example 1 minute to 60 minutes. By adjusting the gap, the thickness of optionally coating (of the thermally conductive composition) in the x-y direction can be adjusted.

The material of the thermally conductive pad (comprising the corrugated sheet with or without being covered by, or embedded in polymeric foam material) can have a thermal conductivity that is at least 0.1 W/m-K, as measure from one surface to another. Specifically, the thermal conductivity of the pad can be within a range from 0.2 to 5 W/m-K, more specifically 0.25 to 2 W/m-K, and even more specifically, 0.30 to 0.49 W/m-K, per ASTM D5470-12 at 30° C.

The compression set of the thermally conducive material pad (comprising the corrugated sheet with or without being covered by, or embedded in polymeric foam material) can be 1 to 10% at 70° C. The compression force deflection (CFD) can be 1 to 20 psi. In some embodiments, the material has a thickness of 0.1 to 25 mm, a thermal conductivity of at least 0.5 W/m-K, a compression set of 1 to 5%, and a compression force deflection of 2 to 12 psi.

The polymeric foam material embedding or covering the corrugated filled elastomeric sheet can have a density of 6 to 35 pounds per cubic foot (pcf). The polymeric foam material can have an average cell diameter of 20 to 500 micrometers.

In an embodiment, a corrugated elastomeric sheet (when flat and uncorrugated) comprising thermally-conductive filler can exhibit a thermal conductivity, per ASTM D5470-12, of at least 0.5 W/m-K, which can vary depending upon the thickness of the sheet and other details of the material and its design.

The compressible thermally conductive material, as described herein, can be used with electronic equipment by positioning it intermediate a first heat transfer surface and a second heat transfer surface to provide a thermal pathway therebetween. One heat transfer surface can be a component designed to absorb heat, such as a heat sink or an electronic circuit board. The other (opposed) heat transfer surface can be a heat generating source, such as a heat generating electronic component. Thus, the surface of the compressible thermally conductive material can be generally planar, multi-planar, curved, or complex curved, indented, etc. As mentioned above, for many applications the total thickness (of the material comprising the corrugated elastomeric sheet) can be, taken from peak to peak on opposed flattened surfaces, between 0.1 millimeter (mm) and 25 mm, specifically 0.25 to 15 mm or 10 to 1000 mils (0.254 to 25.4 mm), and typically, but not necessarily, will be small relative to the extents of the lengthwise or widthwise dimensions of foam pad as defined along the x- and y-axes.

Another aspect is a thermal management assembly comprising a thermally conductive material as described above that is disposed and compressed between a first adjacent heat transfer surface and a second adjacent heat transfer surface, wherein the thickness of the thermally conductive material provides a thermally conductive pathway therebetween. Specifically, the top surfaces of the front ridges or top surfaces of the back ridges of the corrugated filled elastomeric sheet are in contact with a heat generating source. The heat generating source can be an electronic element, a device or component thereof, and the other one of the top surfaces of the front ridges or the top surfaces of the back ridges can be in contact with a thermal dissipation element. The thermal dissipation member can be a heat sink or a circuit board. In an embodiment, a pressure-sensitive (PSA) or other adhesive can be used to secure the compressible thermally conductive material in place between two components in a wide variety of applications, including various kinds of electronic equipment. Applications can include, by way of example, telecom base stations, consumer electronics such as cell phones, computer monitors, plasma TVs, automotive electronic components and systems, circuit boards, card cages, vents, covers, PCMCIA cards, back or face planes, shielding caps or cans, or I/O connector panels of an electronic device, or of an enclosure or cabinet therefore. It will be appreciated that there are a number of other various other applications requiring a resilient, thermally conductive sheet material.

### EXAMPLES

Sample compressible thermally conductive sheets were prepared as follows. A near-solid polyurethane material was molded in the shape of a corrugated sheet. Examples 1 to 17 are listed in Table 2 below. In Table 2, the polyurethane material was based on PORON 92 grade polyurethane foam. The overall sample thickness is 0.0309 inch (0.785 mm) and peak to peak spacing across the corrugated sheet was approximately 0.045 inch (1.14 mm).

Sample preparation involved production of a small scale, clamshell male-female mold with a corrugated pattern built into it. This way, the peak to peak distance across all sheets can be very similar. However, sample thickness will vary as the gap between the top and bottom mold plates increases. To mold the corrugated sheet, all urethane ingredients were mixed together, save the isocyanate. This includes any additives for increasing thermal conductivity. Finally the isocyanate was blended in with use of a Flacktek® speed mixer. The urethane was poured into and spread over the mold. The mold was closed and heated at 75° C. for 30 minutes to cure the foam.

The sample had a density of 25 pcf (400 kg/m³), including the air gas in the valley. Various fillers and loadings thereof were used in the composition for making the corrugated sheet as shown in Table 1.

TABLE 1

| Component | Description | Commercial Source* |
|---|---|---|
| Filler A | CarboTherm ® PCTH3MHF boron nitride platelets, avg. | Saint-Gobain |
| | particle size 0.3 to 30 micrometers | |
| Filler B | Granoc XN-100-25Z Graphite firber in 25 mm lengths | Nippon Graphite Fiber Corp |
| Filler C | Granoc XN-100-03Z Graphite firber in 25 mm lengths | Nippon Graphite Fiber Corp |
| Filler D | Granoc XN-100-05M Graphite firber in 25 mm lengths | Nippon Graphite Fiber Corp |
| Filler E | Surface Enhanced Flake Graphite (SEF-G)-3807 | Asbury Carbons |

The sheets were then tested for thermal conductivity, in accordance with ASTM D5470-12, as detailed in Table 2. Two testing devices were used to measure the thermal conductivity of samples, an Anter Unitherm® 2022 (ASTM E1530-11) test apparatus and a T.I.M. test apparatus by Analysis Tech (ASTM D5470-12). Both devices present thermal conductivity in W/m-K. Thermal conductivities of compressible materials vary with the pressure and gap during testing. Both methods use three measurements, applying fixed pressure or a fixed gap to the material. Values of thermal conductivity here are based off the 20 psi measurement. The test results are shown in Table 2.

TABLE 2

| | | | | Thermal | Thermal | Thermal |
|---|---|---|---|---|---|---|
| | | Filler | Thick- | Conductivity | Conductivity | Conductivity |
| | | (wt. | ness | at 30° C. | at 60° C. | at 90° C. |
| Ex. | Filler | %) | (inch) | (W/m-K) | (W/m-K) | (W/m-K) |
| 1 | Alumi- | 20 | 0.0190 | 0.145 | 0.181 | 0.186 |
| | na tri- | | | | | |
| | hydrate | | | | | |
| 2 | Filler A | 33 | 0.0309 | 0.266 | 0.356 | 0.373 |
| 3 | Filler A | 42 | 0.0359 | 0.264 | 0.333 | 0.342 |
| 4 | Filler A | 43 | 0.0400 | 0.161 | 0.187 | 0.203 |
| 5 | Filler B | 20 | 0.0433 | 0.433 | 0.585 | 0.600 |
| 6 | Filler B | 25 | 0.0406 | 0.490 | 0.724 | 0.747 |
| 7 | Filler C | 25 | 0.0406 | 0.317 | 0.414 | 0.458 |
| 8 | Filler C | 30 | 0.0383 | 0.386 | 0.539 | 0.572 |
| 9 | Filler C | 35 | 0.0450 | 0.414 | 0.564 | 0.606 |
| 10 | Filler C | 40 | 0.0457 | 0.315 | 0.399 | 0.425 |
| 11 | Filler C | 45 | 0.0539 | 0.349 | 0.431 | 0.447 |
| 12 | Filler D | 25 | 0.0315 | 0.310 | 0.414 | 0.425 |
| 13 | Filler D | 35 | 0.0547 | 0.220 | 0.240 | 0.246 |
| 14 | Filler E | 11 | 0.0322 | 0.200 | 0.250 | 0.265 |
| 15 | Filler E | 15 | 0.0396 | 0.315 | 0.416 | 0.431 |
| 16 | Filler E | 25 | 0.0412 | 0.279 | 0.368 | 0.409 |
| 17 | Filler E | 30 | 0.0438 | 0.337 | 0.420 | 0.439 |

Based on the results in Table 2, compressible thermally conductive sheets as described herein were shown to provide thermal conductivity for heat management.

This disclosure further encompasses the following embodiments.

### Embodiment 1

A compressible thermally conductive material in the form of a sheet comprising a plurality of elongated walls that are substantially parallel in an x-y plane, wherein the elongated walls comprise particles of thermally conductive filler dispersed in a polymeric matrix material; wherein each of the elongated walls extend in a direction of thickness that slants from a bottom point to a top point, and wherein adjacent walls slant in alternate directions to a vertical line in the direction of thickness.

### Embodiment 2

The compressible thermally conductive material of Embodiment 1, wherein adjacent elongated walls are separated from each other in the sheet and the elongated walls are embedded in a polymeric foamed material.

### Embodiment 3

The compressible thermally conductive material of Embodiment 1 or 2, wherein adjacent elongated walls are connected to each other in the sheet, thereby forming an elongated ridge or an elongated groove connecting the elongated walls.

### Embodiment 4

The compressible thermally conductive material of any of Embodiments 1-3, comprising a corrugated elastomeric sheet, having corrugated front and back surfaces, formed from a composition comprising particles of thermally conductive filler dispersed in a polymeric matrix material; wherein, in a cross-sectional view, the sides of the corrugated elastomeric sheet joining tops of front ridges to bottom of front grooves in the corrugated elastomeric sheet resiliently form an angle of less than 90 degrees to the horizontal; wherein the corrugated elastomeric sheet has a porosity of 0 to 25%; and wherein the corrugated elastomeric sheet is optionally embedded, at least partially, in a sheet of polymeric foam having porosity greater than 10%.

### Embodiment 5

The compressible thermally conductive material of Embodiment 4, wherein the corrugated elastomeric sheet comprises 1-20 ridges walls per centimeter.

### Embodiment 6

The compressible thermally conductive material of Embodiment 4 or 5 wherein each front ridge and each back ridge of the corrugated elastomeric sheet, in cross-sectional view, independently forms a curved, flat, or pointed top surface, at least before compression of the compressible thermally conductive material.

### Embodiment 7

The compressible thermally conductive material of any of Embodiments 4-6 wherein, in cross-sectional view, the peak surface of each front ridge or each bottom ridge, or both, in the corrugated elastomeric sheet forms a flat surface.

### Embodiment 8

The compressible thermally conductive material of any of Embodiments 4-7 wherein both the top surfaces of the front ridges or the top surfaces of the back ridges, or both, in cross-sectional view, form parallel flat surfaces capable of adjacent contact, respectively, with a flat heat source and a flat heat sink.

### Embodiment 9

The thermally conductive material of any of Embodiments 4-8 wherein, in the corrugated elastomeric sheet, sides joining the top of the front ridges to the bottom of adjacent front grooves, in cross-sectional view, form an angle of less than 20 to 70 degrees, to a horizontal.

### Embodiment 10

The thermally conductive material of any of Embodiments 1-9 wherein the corrugated elastomeric sheet has a ratio of peak-to-peak distance to peak vertical distance, between front ridges and adjacent back ridge, when the material is not compressed, of 5:1 to 1:2.

### Embodiment 11

The thermally conductive material of any of Embodiments 4-10 wherein the corrugated sheet has a flat thickness (uncorrugated) of from 20 to 2000 micrometers and wherein the flat thickness is less than 50% of the corrugated thickness.

### Embodiment 12

The thermally conductive material of any of Embodiments 1-11 wherein the polymer matrix comprises primarily polyurethane or silicone.

### Embodiment 13

The thermally conductive material of Embodiment 12 wherein the polymeric composition of the polymeric matrix material comprises at least 60% polyurethane or silicone optionally blended with a silicone, polyolefin, polyester, polyamide, fluorinated polymer, polyalkylene oxide, polyvinyl alcohol, ionomer, cellulose acetate, polystyrene, or a combination comprising at least one of the foregoing.

### Embodiment 14

The thermally conductive material of any of Embodiments 4-13 wherein the corrugated filled elastomeric sheet comprises a polymeric matrix material that is polyurethane.

### Embodiment 15

The thermally conductive material of any of Embodiments 4-14 wherein the corrugated elastomeric sheet comprises 10 to 60 weight % of the thermally conductive particulate filler having a thermal conductivity of 25 W/m-K to 1000 W/m-K.

### Embodiment 16

The thermally conductive material of Embodiment 14 wherein the particulate filler is a metal or non-metal oxide, nitride, carbide, or boride, carbon, metal, or a combination comprising at least one of the foregoing.

### Embodiment 17

The thermally conductive material of Embodiment 16 wherein the particulate filler comprises boron nitride or graphite particles, or both.

### Embodiment 18

The thermally conductive material of any of Embodiments 4-17 wherein the corrugated elastomeric sheet is at least partially covered, on at least one of the front and back surface, by a layer of polymeric foam material.

### Embodiment 19

The thermally conductive material of Embodiment 18 wherein the top front ridges or back ridges, or both, of the corrugated elastomeric sheet are exposed on the surface of the thermally conductive material and optionally extends beyond, respectively, a surface of the polymeric foam material.

### Embodiment 20

The thermally conductive material of Embodiment 18 wherein the corrugated elastomeric sheet is embedded within a sheet of polymeric foam material, a surface of which covers the front ridges or back ridges, or both.

### Embodiment 21

The thermally conductive material of Embodiment 18 wherein, in the absence of the compression on the material surface, a void space is present under the front or back ridges, or both, of the corrugated elastomeric sheet and, respectively, over front or back surfaces, or both, of a layer of polymeric foam material, which void space is capable of decreasing under compression.

### Embodiment 22

The thermally conductive material of Embodiment 18 wherein the corrugated elastomeric sheet is at least partially covered, on one of either the front or back surface by a layer of polymeric foam material, but not covered on the other of the front or back surface by a layer of polymeric foam material.

### Embodiment 23

The thermally conductive material of Embodiment 18 wherein the polymeric foam material comprises less volume percent of thermally conductive filler than in the corrugated elastomeric sheet or wherein the polymeric foam material comprises greater porosity than in the corrugated elastomeric sheet.

### Embodiment 24

The thermally conductive material of any of Embodiments 1-23 wherein the sheet has a thermal conductivity that is at least 0.1 W/m-K.

### Embodiment 25

The compressible thermally conductive material of any of Embodiments 1-24 comprising a foamed polymeric material having opposed upper and lower surfaces embedding a corrugated elastomeric sheet but in which at least one or both of a top portion of a plurality of ridges or bottom portion of a plurality of grooves, or both, have been removed and wherein, in cross-sectional view through its thickness, the thermally conductive material comprises a plurality of columns which columns extend in a slanted direction from a back surface, or surface portion, to an upper surface, or surface portion, of the material, wherein consecutive adjacent columns slant in alternate directions a surface; wherein each of said columns are adjacent to two other columns and slant in a direction towards one of the two adjacent columns and in the direction away from the other of the two adjacent columns such that the tops of two adjacent columns alternate, in the x-direction, between being slanted towards each other and being slanted away from each other; and; wherein the corrugated elastomeric sheet comprises particles of thermally conductive filler dispersed in a polymeric matrix material having porosity less than 25% and wherein the sheet of polymeric foam material has a porosity of greater than 10% and optionally comprises particles of thermally conductive filler.

### Embodiment 26

A method of making a compressible thermally conductive material, comprising embedding a corrugated elastomeric sheet material in a foamed material to form an intermediate sheet material, wherein the common sides of the front ridges and front grooves in the corrugated elastomeric sheet resiliently form an angle of less than 90 degrees to an x-direction perpendicular to the thickness of the intermediate sheet material, thereby forming an intermediate material; where at least one, or both, of a top or bottom surface layer, or both, of the intermediate material is removed so that, in cross-sectional view through its thickness, at least one, or both, of an upper portion of the front ridges or a bottom portion, or both, of the front grooves ridges are absent such that the thermally conductive material comprises: a plurality of columns formed from a filled elastomeric material, which columns extend from a lower surface or portion of the material to the upper surface or portion of the material, wherein consecutive columns slant at an angle in alternate directions from a perpendicular line joining the top and bottom surfaces such that each of said columns are adjacent to two other columns and slant in a direction towards one of the two adjacent columns and in the direction away from the other of the two adjacent columns.

### Embodiment 27

A thermal management assembly comprising the thermally conductive material of any of Embodiments 1-26 or 28-30 disposed and compressed between a first adjacent heats transfer surface and a second adjacent heat transfer surface, wherein the thickness of the thermally conductive material provides a thermally conductive pathway therebetween.

### Embodiment 28

A compressible thermally conductive material comprising a corrugated elastomeric sheet, having corrugated front and back surfaces, formed from a composition comprising particles of thermally conductive filler dispersed in a polymeric matrix material; wherein, in a cross-sectional view, the sides of the corrugated elastomeric sheet joining tops of front ridges to bottom of front grooves in the corrugated elastomeric sheet resiliently form an angle of less than 90 degrees to the horizontal; wherein the corrugated elastomeric sheet has a porosity of 0 to 25%; and wherein the corrugated elastomeric sheet is optionally embedded, at least partially, in a sheet of polymeric foam having porosity greater than 10%.

### Embodiment 29

A compressible thermally conductive material comprising a polymeric foamed material, having opposed upper and lower surfaces, embedding substantially parallel elongated elastomeric walls comprising particles of thermally conductive filler dispersed in a polymeric matrix material having porosity less than 25%, wherein the polymeric foam material has a porosity of greater than 10%, and optionally comprises particles of thermally conductive filler; wherein the elongated elastomeric walls form, in cross-sectional view through the thickness of the material, a plurality of columns extending in a slanted direction from a back surface, or surface portion thereof, to an upper surface, or surface portion thereof, of the material, wherein adjacent columns slant in alternate directions to a vertical line through the thickness of the material.

### Embodiment 30

The compressible thermally conductive material of Embodiment 29, wherein the material is a product of a process in which the substantially parallel elongated elastomeric walls are made by removing at least one or both of top portions of a plurality of ridges or bottom portions, or both of a plurality of grooves.

Ranges disclosed herein are inclusive of the recited endpoint and combinable (e.g., ranges of “up to 25 wt. %, or, more specifically, 5 wt. % to 20 wt. %”, is inclusive of the endpoints and all intermediate values of the ranges of “5 wt. % to 25 wt. %,” etc.). “Combination” is inclusive of blends, mixtures, alloys, reaction products, and the like. Also, “combinations comprising at least one of the foregoing” clarifies that the list is inclusive of each element individually, as well as combinations of two or more elements of the list, and combinations of one or more elements of the list with non-list elements. Furthermore, the terms “first,” “second,” and so forth, herein do not denote any order, quantity, or importance, but rather are used to distinguish one element from another, and the terms “a” and “an” herein do not denote a limitation of quantity, but rather denote the presence of at least one of the referenced item. The described elements can be combined in any suitable manner in the various embodiments. As used herein, the terms sheet, film, plate, and layer, are used interchangeably, and are not intended to denote size.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While the invention has been described with reference to several embodiments thereof, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1. A compressible thermally conductive material in the form of a sheet comprising a plurality of elongated walls that are substantially parallel in an x-y plane, wherein the elongated walls comprise particles of thermally conductive filler dispersed in a polymeric matrix material;
wherein each of the elongated walls extend in a direction of thickness that slants from a bottom point to a top point, and wherein adjacent walls slant in alternate directions to a vertical line in the direction of thickness.

2. The compressible thermally conductive material of claim 1, wherein adjacent elongated walls are separated from each other in the sheet and the elongated walls are embedded in a polymeric foamed material.

3. The compressible thermally conductive material of claim 1, wherein adjacent elongated walls are connected to each other in the sheet, thereby forming an elongated ridge or elongated groove, or both connecting the elongated walls.

4. The compressible thermally conductive material of claim 1, comprising a corrugated elastomeric sheet, having corrugated front and back surfaces, and comprising particles of a thermally conductive filler dispersed in a polymeric matrix material;
wherein, in a cross-sectional view, the sides of the corrugated elastomeric sheet joining tops of front ridges to bottom of front grooves in the corrugated elastomeric sheet resiliently form an angle of less than 90 degrees to the horizontal;
wherein the corrugated elastomeric sheet has a porosity of 0 to 25%; and
wherein the corrugated elastomeric sheet is optionally at least partially embedded in a sheet of polymeric foam having porosity greater than 10%.

5. The compressible thermally conductive material of claim 4, wherein the corrugated elastomeric sheet comprises 1 to 20 ridges per centimeter.

6. The compressible thermally conductive material of claim 4, wherein each front ridge and each back ridge of the corrugated elastomeric sheet, in cross-sectional view, independently forms a curved, flat, or pointed top surface, at least before compression of the compressible thermally conductive material.

7. The compressible thermally conductive material of claim 4, wherein, in cross-sectional view, the peak surface of each front ridge or each bottom ridge, or both, in the corrugated elastomeric sheet forms a flat surface.

8. The compressible thermally conductive material of claim 1, wherein both the top surfaces of the front ridges or the top surfaces, or both, of the back ridges, in cross-sectional view, form parallel flat surfaces capable of adjacent contact, respectively, with a flat heat source and a flat heat sink.

9. The thermally conductive material of claim 4, wherein, in the corrugated elastomeric sheet, sides joining the top of the front ridges to the bottom of adjacent front grooves, in cross-sectional view, form an angle of less than 20 to 70 degrees, to a horizontal.

10. The thermally conductive material of claim 4, wherein the corrugated elastomeric sheet has a ratio of peak-to-peak distance to peak vertical distance, between front ridges and adjacent back ridge, when the material is not compressed, of 5:1 to 1:2.

11. The thermally conductive material of claim 4, wherein the sheet has an uncorrugated flat thickness of 20 to 2000 micrometers and wherein the flat thickness is less than 50% of the corrugated thickness.

12. The thermally conductive material of claim 4, wherein the polymeric matrix material comprises at least 60% polyurethane or silicone optionally blended with silicone, polyolefin, polyester, polyamide, fluorinated polymer, polyalkylene oxide, polyvinyl alcohol, ionomer, cellulose acetate, polystyrene, or a combination comprising at least one of the foregoing.

13. The thermally conductive material of claim 4, wherein the corrugated elastomeric sheet comprises 10 to 60 weight percent of the thermally conductive particulate filler having a thermal conductivity of 25 to 1000 W/m-K.

14. The thermally conductive material of claim 4, wherein the corrugated elastomeric sheet is at least partially covered, on at least one of the front and back surface, by a layer of polymeric foam material.

15. The thermally conductive material of claim 14, wherein the top front ridges or back ridges, or both, of the corrugated elastomeric sheet are exposed on the surface of the thermally conductive material and optionally extends beyond, respectively, a surface of the polymeric foam material.

16. The thermally conductive material of claim 14, wherein the elastomeric sheet is embedded within a sheet of polymeric foam material, a surface of which covers the front ridges or back ridges, or both.

17. The thermally conductive material of claim 14, wherein, in the absence of the compression on the material surface, a void space is present under the front or back ridges, or both, of the corrugated elastomeric sheet and, respectively, over front or back surfaces, or both of a layer of polymeric foam material, which void space is capable of decreasing under compression.

18. The thermally conductive material of claim 14, wherein the corrugated elastomeric sheet is at least partially covered, on one of either the front or back surface by a layer of polymeric foam material, but not covered on the either of the front or back surface by a layer of polymeric foam material.

19. The thermally conductive material of claim 14, wherein the polymeric foam material comprises less volume percent of thermally conductive filler than in the corrugated elastomeric sheet or wherein the polymeric foam material comprises greater porosity than in the corrugated elastomeric sheet, or both.

20. The thermally conductive material of claim 1, wherein the sheet has a thermal conductivity that is at least 0.1 W/m-K.

21. The compressible thermally conductive material of claim 1, comprising a foamed polymeric material having opposed upper and lower surfaces embedding a corrugated elastomeric sheet but in which at least one or both of a top portion of a plurality of ridges or bottom portion of a plurality of grooves, or both, have been removed and wherein, in cross-sectional view through its thickness, the thermally conductive material comprises a plurality of columns which columns extend in a slanted direction from a back surface, or surface portion, to an upper surface, or surface portion, of the material, wherein consecutive adjacent columns slant in alternate directions a surface;
wherein each of said columns are adjacent to two other columns and slant in a direction towards one of the two adjacent columns and in the direction away from the other of the two adjacent columns such that the tops of two adjacent columns alternate, in the x-direction, between being slanted towards each other and being slanted away from each other; and;
wherein the corrugated elastomeric sheet comprises particles of thermally conductive filler dispersed in a polymeric matrix material having porosity less than 25% and wherein the sheet of polymeric foam material has a porosity of greater than 10% and optionally comprises particles of thermally conductive filler.

22. A method of making a compressible thermally conductive material, the method comprising:
embedding a corrugated elastomeric sheet material in a foamed material to form an intermediate sheet material, wherein the common sides of the front ridges and front grooves in the corrugated elastomeric sheet resiliently form an angle of less than 90 degrees to an x-direction perpendicular to the thickness of the intermediate sheet material, thereby forming an intermediate material;
where at least one, or both, of a top or bottom surface layer of the intermediate material is removed so that, in cross-sectional view through its thickness, at least one, or both, of an upper portion of the front ridges or a bottom portion of the front grooves, or both are absent such that the thermally conductive material comprises:
a plurality of columns formed from a filled elastomeric material, which columns extend from a lower surface or portion of the material to the upper surface or portion of the material, wherein consecutive columns slant at an angle in alternate directions from a perpendicular line joining the top and bottom surfaces such that each of said columns are adjacent to two other columns and slant in a direction towards one of the two adjacent columns and in the direction away from the other of the two adjacent columns.

23. A thermal management assembly comprising the thermally conductive material of claim 1 disposed and compressed between a first adjacent heat transfer surface and a second adjacent heat transfer surface, wherein the thickness of the thermally conductive material provides a thermally conductive pathway therebetween.
